(19) United States
(12) Patent Application Publication
(10) Pub. No.: US 2022/0035317 A1
(43) Pub. Date: Feb. 3, 2022

(54) WEARABLE DEVICES WITH OVERMOLDED ELECTRONIC COMPONENTS AND RELATED METHODS

(71) Applicant: Facebook Technologies, LLC, Menlo Park, CA (US)

(72) Inventors: Daniel Thomas Porter, Woodinville, WA (US); Phelan Miller, Duvall, WA (US); Khanh Nguyen, Seattle, WA (US)

(21) Appl. No.: 17/216,964

(22) Filed: Mar. 30, 2021

Related U.S. Application Data
(60) Provisional application No. 63/057,725, filed on Jul. 28, 2020.

(51) Int. Cl. G04G 17/04; H05K 1/02; H05K 3/28; G04G 21/02

(52) U.S. Cl. CPC G04G 17/04; H05K 1/028; G04G 21/025; H05K 3/284; H05K 1/0274

(57) ABSTRACT

The disclosed wearable devices may include a wearable body sized and configured to be worn on a user's body part and at least one electronic component within the wearable body. The wearable body may include a flexible material for wrapping at least partially around the user's body part. The at least one electronic component may be overmolded within the flexible material of the wearable body. Various other methods, systems, and devices are also disclosed.

### CROSS-REFERENCE TO RELATED APPLICATION

This application claims the benefit of U.S. Provisional Patent Application Ser. No. 63/057,725, titled “WEARABLE DEVICES WITH OVERMOLDED ELECTRONIC COMPONENTS AND RELATED METHODS,” filed Jul. 28, 2020, the entire disclosure of which is incorporated herein by reference.

### BRIEF DESCRIPTION OF THE DRAWINGS

The accompanying drawings illustrate a number of example embodiments and are a part of the specification. Together with the following description, these drawings demonstrate and explain various principles of the present disclosure.

FIG. 1 is a plan view of a wearable device, according to at least one embodiment of the present disclosure.

FIG. 2 is a perspective view of a wearable device, according to at least one embodiment of the present disclosure.

FIG. 3 is a cross-sectional view of a wearable device, according to at least one embodiment of the present disclosure.

FIGS. 4A-4C are side views of a molding apparatus, showing various stages of forming a wearable device in the molding apparatus, according to at least one embodiment of the present disclosure.

FIGS. 5A and 5B are side views of a molding apparatus, showing various stages of forming a wearable device in the molding apparatus, according to at least one additional embodiment of the present disclosure.

FIG. 6 is a flow diagram illustrating a method of forming a wearable device, according to at least one embodiment of the present disclosure.

FIG. 7 is a cross-sectional view of a wearable device including an overmolded haptic actuator, according to at least one embodiment of the present disclosure.

FIG. 8A is a plan view of a wearable device component including an accelerometer taken from line A-A of FIG. 8B, according to at least one embodiment of the present disclosure. FIG. 8B is a side view of the wearable device component taken from line B-B of FIG. 8A. FIG. 8C is a plan view of the wearable device component taken from line C-C of FIG. 8D after an extension supporting the accelerometer is folded into a final position. FIG. 8D is a side view of the wearable device component taken from line D-D of FIG. 8C.

FIG. 9 is a perspective view of a portion of a wearable device, according to at least one additional embodiment of the present disclosure.

FIG. 10 is a perspective view of a portion of a wearable device, according to at least one other embodiment of the present disclosure.

FIG. 11 is an illustration of example augmented-reality glasses that may be used in connection with embodiments of this disclosure.

FIG. 12 is an illustration of an example virtual-reality headset that may be used in connection with embodiments of this disclosure.

FIG. 13 is an illustration of example haptic devices that may be used in connection with embodiments of this disclosure.

FIG. 14 is an illustration of an example virtual-reality environment according to embodiments of this disclosure.

FIG. 15 is an illustration of an example augmented-reality environment according to embodiments of this disclosure.

FIGS. 16A and 16B are illustrations of an exemplary human-machine interface configured to be worn around a user's lower arm or wrist.

FIGS. 17A and 17B are illustrations of an exemplary schematic diagram with internal components of a wearable system.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within the scope of the appended claims.

### DETAILED DESCRIPTION OF EXAMPLE EMBODIMENTS

Wearable devices may be configured to be worn on a user's body part, such as a user's wrist or arm. Such wearable devices may be configured to perform various functions. A wristband system may be an electronic device worn on a user's wrist that performs functions such as delivering content to the user, executing social media applications, executing artificial-reality applications, messaging, web browsing, sensing ambient conditions, interfacing with head-mounted displays, monitoring the health status of the user, etc. Wearable devices with an increased number of functions may be somewhat bulky and intrusive, such as to house the appropriate sensors, batteries, and other electronic components.

The present disclosure is generally directed to wearable devices that include a flexible material and at least one electronic component overmolded within the flexible material. As will be explained in greater detail below, embodiments of the present disclosure may include a wristwatch including a watch body and a watchband. The watchband may include the electronic component(s) overmolded within a flexible material. By positioning the electronic component(s) within the flexible material of the watchband, certain functions and operations may be offloaded from the watch body to the watchband, which may improve operation of the wristwatch and/or may reduce a size of the watch body.

Features from any of the embodiments described herein may be used in combination with one another in accordance with the general principles described herein. These and other embodiments, features, and advantages will be more fully understood upon reading the following detailed description in conjunction with the accompanying drawings and claims.

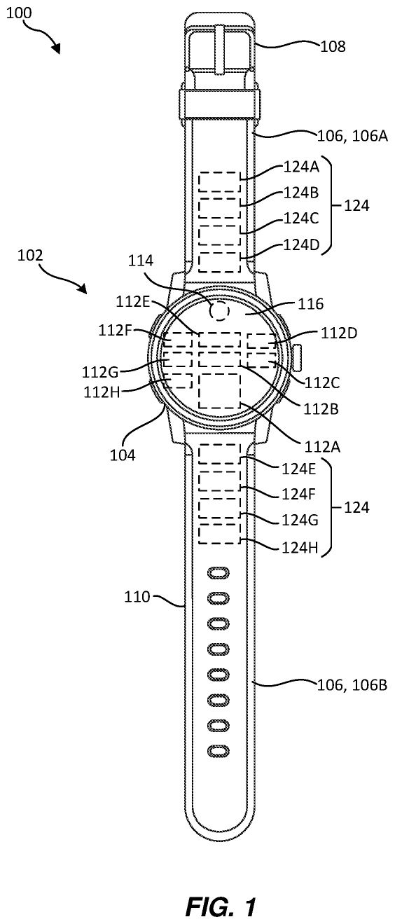

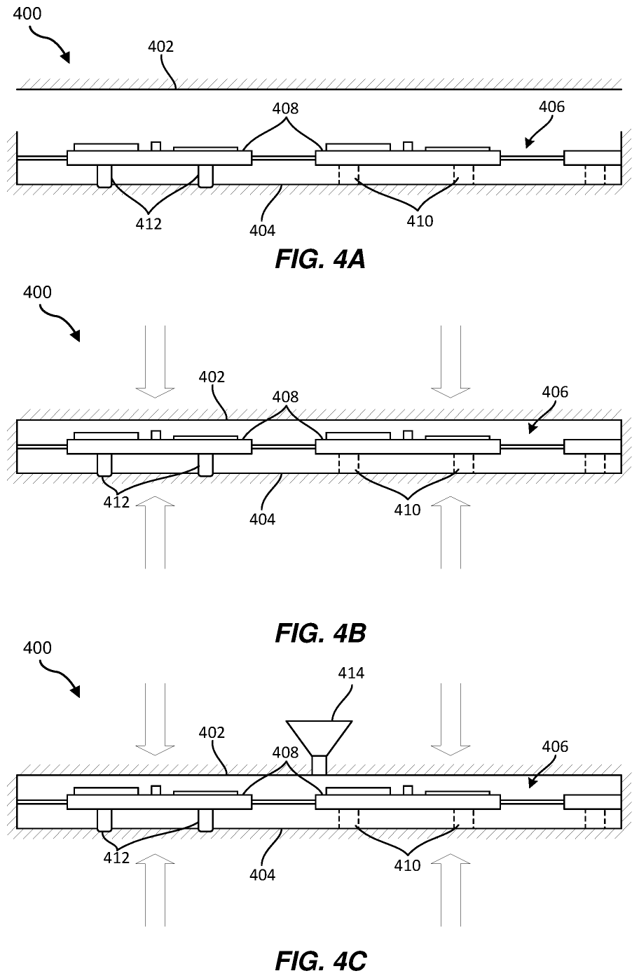

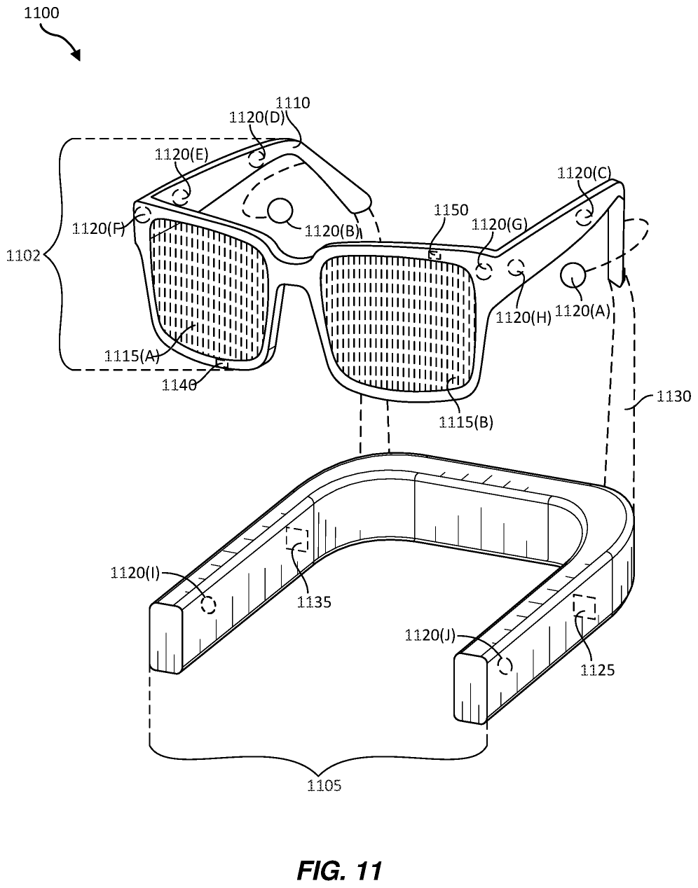

The following will provide, with reference to FIGS. 1-3 and 8A-10, detailed descriptions of example wearable devices and components thereof. With reference to FIGS. 4A-6, detailed descriptions of methods of forming wearable devices will be provided. With reference to FIGS. 11-17B, the following will provide detailed descriptions of example systems and devices that may be used in conjunction with embodiments of the present disclosure.

FIG. 1 is a plan view of a wearable device 100 that includes a wearable body 102, such as a watch body 104 coupled to a watchband 106. As illustrated in FIG. 1, the wearable device 100 may be a wristwatch (e.g., a so-called “smartwatch”). In additional examples, the wearable device 100 may be a wristband, armband, neckband, finger ring, glove, vest, headband, leg band, etc. The wearable device 100 may be formed to have any size and/or shape that is configured for a user to wear the wearable device on a corresponding body part (e.g., a wrist, a hand, an upper arm, a head, a neck, a leg, a torso, etc.). Aspects of the following description of the wearable device 100 as a wristwatch are also applicable to other wearable devices 100. For example, discussions of the watch body 104 and the watchband 106 may be applicable to a sensor and/or display element and a band element of a different wearable device 100.

Referring to FIG. 1, the watchband 106 of the wearable device 100 may include a retaining mechanism 108, such as a buckle (as shown in FIG. 1) or a hook-and-loop fastener, for securing the wearable device 100 to the corresponding body part of the user and/or for adjusting a size of the wearable device 100 to comfortably fit the body part of the user. In additional embodiments, the retaining mechanism 108 may include at least one elastic portion, such as for stretching the watchband 106 to fit on the body part of the user (e.g., over a hand and onto a wrist of the user). In some examples, the watchband 106 may include a first watchband element 106A coupled to a first side of the watch body 104 and a second watchband element 106B coupled to a second, opposite side of the watch body 104.

The watchband 106 may include a flexible material 110 for at least partially conforming to the user's body part (e.g., wrist). For example, the flexible material 110 may include a thermoplastic elastomer, thermoplastic rubber, or liquid silicone rubber. In some embodiments, the flexible material 110 may be or include a silicone material, a polyolefin material, a polyurethane material, a fluoroelastomer material, a vulcanisate material, a copolyester material, a styrenic block copolymer material, a neoprene material, a nitrile material, or any other suitable flexible material that can be formed into an appropriate shape and that exhibits sufficient flexibility to conform to the user's body part.

The watch body 104 may include one or more electronic components 112, such as at least one processor 112A, a biometric sensor 112B, a motion sensor 112C, a haptic actuator 112D, a power source 112E, a memory device 112F, a communication element 112G, a tracking element 112H, an image sensor 114, a display element 116, any combination thereof, etc. The at least one processor 112A may be in communication with any of the other electronic components, such as to process signals from and/or to control operation of the other electronic components.

By way of example and not limitation, the display element 116 may include an electronic display, such as one or more liquid crystal displays (LCDs), light emitting diode (LED) displays, organic LED (OLED) displays, digital light project (DLP) micro-displays, liquid crystal on silicon (LCoS) micro-displays, a touch-screen display, and/or any other suitable type of display screen.

As illustrated in FIG. 1, one or more additional electronic components 124 may be located in the watchband 106, instead of or in addition to in the watch body 104. For example, the watchband 106 may include one or more of a processor 124A, a biometric sensor 124B, a motion sensor 124C, a haptic actuator 124D, a power source 124E, a memory device 124F, a communication element 124G, a tracking element 124H, etc. As will be explained in further detail below, the electronic component(s) 124 in the watchband 106 may be overmolded at least partially within the flexible material 110 of the watchband 106.

Although the additional electronic components 124A-124D are shown as located in the first watchband 106A and the additional electronic components 124E-124H are shown as located in the second watchband 106B, the present disclosure is not so limited. The additional electronic components 124 may be physically arranged in any combination of the first watchband 106A and/or the second watchband 106B, such as all in the first watchband 106A, all in the second watchband 106B, or split between the first watchband 106A and the second watchband 106B.

The processor(s) 112A, 124A may include a microprocessor configured to receive and process data from the other electronic components 124 of the watchband 106 and/or from one or more of the other electronic components 112 of the watch body 104. The processor(s) 112A, 124A may also be configured to control operation of the other electronic components 124 of the watchband 106 and/or of one or more of the other electronic components 112 of the watch body 104. The processor 124A of the watchband 106 may be in communication with the at least one processor 112A of the watch body 104, such as through the communication element 124G of the watchband 106 and/or the communication element 112G of the watch body 104. In some embodiments, the processor 124A of the watchband 106 and the at least one processor 112A of the watch body 104 may share and balance processing responsibilities for some operations.

By way of example and not limitation, the biometric sensor(s) 112B, 124B may be or include a heartrate monitor, a pulse oximeter, a skin conductance sensor, a skin temperature sensor, a neuromuscular sensor, any combination thereof, etc. In some embodiments, the biometric sensor 124B of the watchband 106 may include one or more electrodes, optical sensors, or other components that may physically extend through the flexible material 110 of the watchband 106, such as through an aperture in the flexible material 110. Likewise, the biometric sensor 112B of the watch body 104 may include one or more electrodes, optical sensors, or other components that may physically extend through a material on a back surface of the watch body 104.

The motion sensor(s) 112C, 124C may be or include a sensor that is configured to sense changes in position and/or orientation in multiple axes, such as six axes (e.g., x, y, z, roll, pitch, and yaw). For example, the motion sensor(s) 112C, 124C may include a gyroscope, an accelerometer, a global positioning system (“GPS”) receiver, an inertial measurement unit (“IMU”), etc. In some examples, the motion sensor(s) 112C, 124C may be configured for use as a step counter, a position sensor, an orientation sensor, any combination thereof, etc.

The haptic actuator(s) 112D, 124D may be configured to provide haptic feedback (e.g., tactile feedback that an action has been completed, etc.) to the user and/or to provide a tactile signal (e.g., an indication of a message received, an alarm, a reminder, an indication of a milestone reached, a physical sensation coinciding with an audible sound, a physical sensation indicating an interaction with the wearable device 100 has been recorded, pressure to provide the sensation of physically touching a digital object, etc.) to the user. For example, the haptic actuator(s) 112D, 124D may be or include a linear resonant actuator (“LRA”), an eccentric rotating mass (“ERM”), a haptic jammer, an inflatable bladder, a piezoelectric actuator, any combination thereof, etc.

The power source 124E of the watchband 106 and/or the power source 112E of the watch body 104 may be configured to provide electrical power to the other electronic components 124 of the watchband 106 and/or to the other electronic components 112 of the watch body 104. By way of example and not limitation, the power source(s) 112E, 124E may include a battery cell (e.g., an alkaline battery, a lithium-ion battery, a nickel cadmium battery, etc.), a capacitor, or a combination thereof. In some examples, the power source 124E of the watchband 106 may be a curved battery that has a curvature intended to correspond to a curvature of a user's wrist. In additional embodiments, the power source 124E of the watchband 106 may include a flexible battery cell configured to at least partially flex upon being wrapped around the user's wrist.

The memory device(s) 112F, 124F may be configured to store digital information for later retrieval. For example, the memory device(s) 112F, 124F may be configured to store music files, digital images, digital videos, sensor data, digital instructions and software programs, haptic actuator activation profiles, address books, weather data, user profile data, etc. The memory device(s) 112F, 124F may include a dynamic random-access memory (“DRAM”) element, a read-only memory (“ROM”) element, a NAND Flash memory element, or any other suitable digital memory element or combination thereof.

The communication elements 112G, 124G may be wired or wireless communication elements 112G, 124G. The communication element 124G of the watchband 106 may be configured to communicate with the communication element 112G of the watch body 104. For example, the communication elements 112G, 124G may provide a digital connection between the watchband 106 and the watch body 104, such as to transmit sensor data or processor results between the watchband 106 and the watch body 104. In additional examples, the communication element(s) 112G, 124G may be configured to communicate with an external device, such as a mobile phone, an artificial-reality device (e.g., an artificial-reality headset or controller), a desktop computer, a tablet computer, a laptop computer, a charging port, a vehicle, a drone, an audio speaker, an electronic display (e.g., a television, a computer monitor, etc.), a printer, an external sensor, any combination thereof, etc.

The tracking element(s) 112H, 124H may include an infrared light-emitting diode (“LED”) or group of infrared LEDs that may facilitate optical tracking of the wearable device 100 in space. For example, in an artificial-reality system, infrared sensors may be positioned (e.g., in a headset, in a stationary tracking sensor, in a controller, etc.) and configured to identify the tracking element(s) 112H, 124H. The tracking element(s) 112H, 124H, when identified and tracked by an appropriate sensor, may indicate information for determining both a position and an orientation of the wearable device 100. In some examples, the flexible material 110 of the watchband 106 and/or at least a portion of the watch body 104 may be at least partially transparent to light emitted by the tracking element 124H, such as infrared light, even though the flexible material 110 and/or watch body 104 may be opaque to visible light.

In some examples, one or more of the electronic components 124 in the watchband 106 may be integrated into a so-called “rigid flex printed circuit board (‘PCB’).” The rigid flex PCB may include rigid portions of PCB material separated by flexible electrical connections (e.g., wires, traces, etc.) that may enable the rigid flex PCB to maintain full functionality while being bent, such as around the user's wrist.

By locating one or more electronic components 124 within the watchband 106, the watch body 104 may be smaller and lighter-weight than if those electronic components 124 were all located within the watch body 104. The watch body 104 may also generate less heat due to the reduced number of electronics within the watch body 104. Additionally or alternatively, the wearable device 100 may include additional capabilities and functionality without altering a size of the watch body 104 by housing the additional electronic component(s) 124 within the watchband 106. In addition, at least partially overmolding the electronic component(s) 124 within the flexible material 110 of the watchband 106 may protect the electronic component(s) 124 from environmental damage while maintaining a form factor that is comfortable for the user to wear and use.

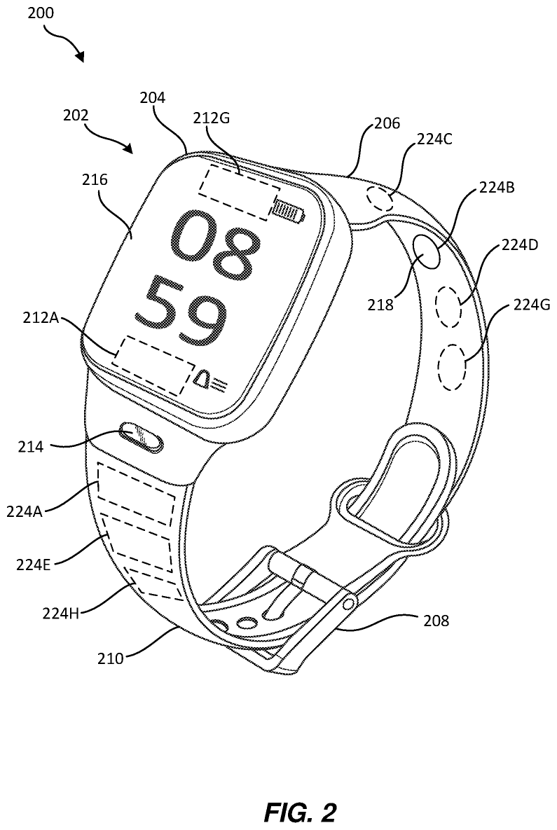

FIG. 2 is a perspective view of a wearable device 200 (e.g., a wristband, a wristwatch, etc.), according to at least one embodiment of the present disclosure. In some respects, the wearable device 200 may be similar to the wearable device 100 described above with reference to FIG. 1. For example, the wearable device 200 may include a wearable body 202, a watch body 204, a watchband 206, and a retaining mechanism 208. The watchband 206 may include a flexible material 210. The watch body 204 may include one or more electronic components 212, and the watchband 206 may include one or more additional electronic components 224, which may be overmolded at least partially within the flexible material 210 of the watchband.

As shown in FIG. 2, the watch body 204 may include at least one processor 212A, a communication element 212G, and a display element 216. The watchband 206 may include at least one processor 224A, a biometric sensor 224B, a motion sensor 224C, a haptic actuator 224D, a power source 224E, a communication element 224G, a tracking element 224H, and an image sensor 214. Thus, in this case, several of the electronic functions of the wearable device 200 may be performed by the electronic components 224 of the watchband 206, which may enable the watch body 204 to be smaller and/or to have a different shape.

As illustrated in FIG. 2, the biometric sensor 224B may include an electrode 218 or other sensing element that extends through the flexible material 210 of the watchband 206, such as through an aperture in the watchband 206. In some embodiments, the electrode 218 may be positioned, shaped, and configured to physically contact a user's skin when the wearable device 200 is worn by a user.

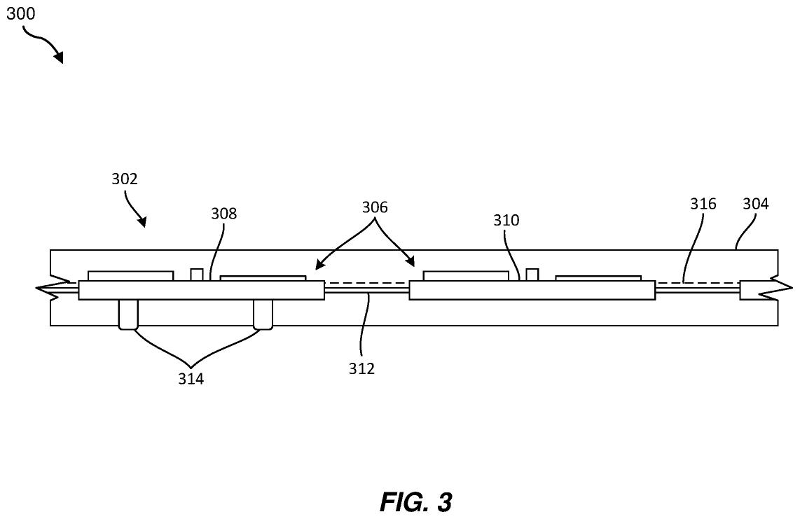

FIG. 3 is a cross-sectional view of a wearable device 300, according to at least one embodiment of the present disclosure. The wearable device 300 may include a wearable body 302 that may be configured to be worn on a user's body part, such as on a wrist, a hand, an upper arm, a head, a neck, a leg, a torso, etc., of the user. For example, the wearable body 302 may be or may form a part of a wristwatch, wristband, watchband, armband, neckband, finger ring, glove, vest, headband, leg band, etc. The wearable body 302 may include a flexible material 304 (e.g., a thermoplastic elastomer, thermoplastic rubber, liquid silicone rubber, a fluoroelastomer, etc.) configured to flex for wrapping at least partially around the user's body part.

Electronic components 306 may be disposed at least partially within the flexible material 304 of the wearable body 302. The electronic components 306 may be overmolded at least partially within the flexible material 304 of the wearable device 300. By way of example and not limitation, the electronic components 306 may be or include any of the electronic components 112, 124 described above with reference to FIG. 1.

The electronic components 306 within the flexible material 304 may include a first PCB 308 and a second PCB 310, which may be coupled (e.g., electrically coupled) to each other via a flexible electrical connection 312, such as flexible conductive wires or traces. The first PCB 308, second PCB 310, and flexible electrical connection 312 may form a rigid flex PCB.

In some examples, the first PCB 308 may be or include a sensor, such as a biometric sensor. Thus, the first PCB 308 may include one or more electrodes 314 that may extend from the first PCB 308 and through the flexible material 304 of the wearable body 302 to be exposed to an environment external to the flexible material 304. For example, the electrodes 314 may be configured for contacting the user's skin when the wearable device 300 is worn by the user, such as to sense a heartrate, skin conductance, neuromuscular signals, etc.

The wearable device 300 may also include a flexible support material 316 embedded within the flexible material 304. For example, the flexible support material 316 may include a woven or non-woven fabric material, such as a woven nylon fabric material. The flexible support material 316 may provide mechanical support to the flexible electrical connections 312 when the wearable device 300 stretches and/or compresses during a bending (e.g., when bent to conform to a user's arm).

FIGS. 4A-4C are side views of a molding apparatus 400, showing various stages of forming a wearable device in the molding apparatus 400, according to at least one embodiment of the present disclosure. The molding apparatus 400 may be an injection molding machine, a compression molding machine, or any other suitable type of molding apparatus. The type of molding apparatus 400 selected may depend on a material to be molded by the molding apparatus 400.

The molding apparatus 400 may include a first mold die 402 and a second mold die 404. A mold cavity 406 may be defined by a space between the first and second mold dies 402, 404 when the mold dies 402, 404 are brought together, as illustrated in FIGS. 4B and 4C.

Referring to FIG. 4A, at least one electronic component 408 of a wearable device may be positioned within the mold cavity 406. For example, any of the electronic components 112, 124 described above may be positioned within the mold cavity 406. In some embodiments, the electronic component(s) 408 may be held in position within the mold cavity 406 at least partially by one or more standoffs 410. The standoffs 410 may include a flexible material, such as a material from which a body of the wearable device is to be formed. In additional embodiments, the standoffs 410 may include one or more rigid pins protruding from a wall of the first mold die 402 and/or the second mold die 404.

In some examples, one or more electrodes 412 may hold at least a portion of the electronic component(s) 408 in position within the mold cavity 406. The first mold die 402 and/or the second mold die 404 may include a feature (e.g., a recess, a protrusion, an aperture, etc.) that is complementary to the electrode(s) 412 for aligning the electronic component(s) 408 in a predetermined position and for enabling the electrode(s) 412 to protrude to an exterior of the material to be molded over the electronic component(s) 408.

As illustrated in FIG. 4B, after the electronic component(s) 408 are positioned within the mold cavity 406, the first mold die 402 and the second mold die 404 may be brought together to enclose the electronic component(s) 408 within the mold cavity 406.

As illustrated in FIG. 4C, flexible material precursor may be injected into the mold cavity 406 to at least partially surround and overmold the electronic component(s) 408. The flexible material precursor may be injected into the mold cavity 406 from a source 414, such as a screw motor drive, a hydraulic press, an electric press, a hopper, a pump, etc. The flexible material precursor may include a precursor for any of the flexible materials 110 described above. The flexible material precursor may, in some examples, be or include a molten flexible material. For example, a liquid silicone rubber material, which may be liquid or semi-liquid at room temperature, may be injected into the mold cavity 406 to cure within the mold cavity 406. In additional examples, a compression molding process may be employed to inject a viscous flexible material precursor into the mold cavity 406, and the mold cavity 406 may be compressed (e.g., two or more mold dies defining the mold cavity 406 may be compressed) to form the material into a desired shape.

The flexible material precursor may be injected into the mold cavity 406 at a pressure and temperature to at least substantially fill the mold cavity 406 around the electronic component(s) 408 without damaging the electronic component(s) 408. For example, the temperature of the flexible material precursor may be maintained at less than 120° C., such as less than 110° C., less than 100° C., less than 90° C., or less than 85° C. By way of further example, the pressure within the mold cavity 406 may be maintained at less than 50 MPa, such as less than 40 MPa, less than 30 MPa, or less than 20 MPa.

After a sufficient amount of the flexible material precursor is injected into the mold cavity 406 to at least substantially fill the mold cavity 406 around the electronic component(s) 408, the mold dies 402, 404 may be allowed to cool to harden the flexible material precursor into a solid or semi-solid flexible material. When the flexible material has been sufficiently solidified, the first mold die 402 and the second mold die 404 may be separated from each other to open the mold cavity 406. The flexible material and the electronic component(s) 408, with the electronic component(s) 408 overmolded at least partially within the flexible material, may be removed from the mold cavity 406.

In some embodiments, the electronic component(s) 408 may be overmolded in a two- or three-step process. For example, a flexible material precursor may first be molded to a first side of the electronic component(s) 408 and a flexible material precursor may next be molded to a second, opposite side of the electronic component(s) 408 in a separate operation. In additional examples, the flexible material precursor may be initially molded into a rough shape and then may be molded again into a final shape. In this case, the final shape may have an improved quality (e.g., surface finish, desired shape and size, etc.) while inhibiting (e.g., reducing, avoiding, etc.) damage to the electronic component(s) 408.

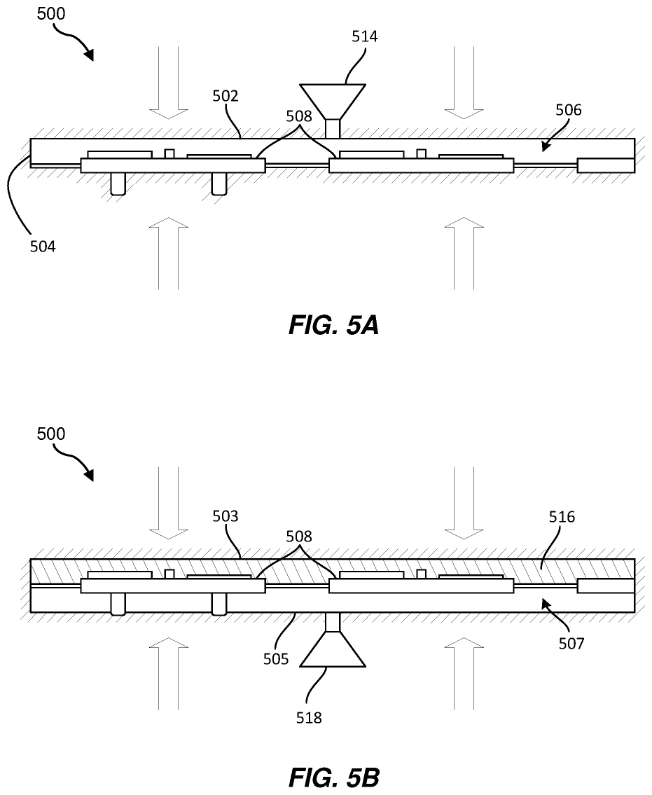

FIGS. 5A and 5B are side views of a molding apparatus 500, showing various stages of forming a wearable device in the molding apparatus 500 in a two-step process, according to at least one additional embodiment of the present disclosure. In some respects, the molding apparatus 500 of FIGS. 5A and 5B may be similar to the molding apparatus 400 described above with referent to FIGS. 4A-4C. For example, the molding apparatus 500 may include a first mold die 502 and a second mold die 504 that may define a mold cavity 506 therebetween when the first and second mold dies 502, 504 are brought together. However, the mold cavity 506 may be shaped and sized to define only a portion of a wearable device to be formed.

Referring to FIG. 5A, the mold cavity 506 may be configured to form a flexible material on one side of at least one electronic component 508 to be overmolded. The electronic component(s) 508 may be positioned within the mold cavity 506 against one of the mold dies 502, 504 such that only one side of the electronic component(s) 508 is exposed to the interior of the mold cavity 506. One or both of the mold dies 502, 504 may include a feature (e.g., protrusion, cavity, recess, pattern, etc.) that is complementary to the portions of the electronic component(s) 508 that abut against the mold die(s) 502, 504. A flexible material precursor may be injected into the mold cavity 506 from a source 514, such as a screw motor drive, a hydraulic press, an electric press, a hopper, a pump, etc. The flexible material precursor may include a precursor for any of the flexible materials 110 described above. The flexible material precursor may be allowed to at least partially harden (e.g., cure, solidify, etc.) to form a flexible material 516 (FIG. 5B) coupled to one side of the electronic component(s) 508.

As shown in FIG. 5B, the molding apparatus 500 may include a third mold die 503 and a fourth mold die 505 with another mold cavity 507 therebetween. The other mold cavity 507 may have a size and shape for forming a flexible material on an opposite side of the electronic component(s) 508 from the flexible material 516 that was formed in the mold cavity 506, as described above with reference to FIG. 5A. The other mold cavity 507 may be configured to contain the electronic component(s) 508 and the flexible material 516 coupled to one side of the electronic component(s) 508. The other mold cavity 507 may be open on the side of the electronic component(s) 508 opposite the flexible material 516.

A flexible material precursor may be injected into the other mold cavity 507 from a source 518 to form the flexible material 516 on the remaining side of the electronic component(s) 508. The flexible material precursor may then be hardened (e.g., cured, solidified, etc.) and the resulting assembly removed from the other mold cavity 507.

In some examples of this two-step molding process, standoffs may be omitted. In the initial molding step (FIG. 5A), the electronic component(s) 508 may be supported in the mold cavity 506 by abutting directly against the mold die(s) 502, 504 without any standoffs. In the second molding step (FIG. 5B), the initially formed flexible material 516 may support the electronic components 508 in the other mold cavity 507 without any additional standoffs. This process may reduce potential discontinuities in the flexible material 516 that might otherwise occur if standoffs were used.

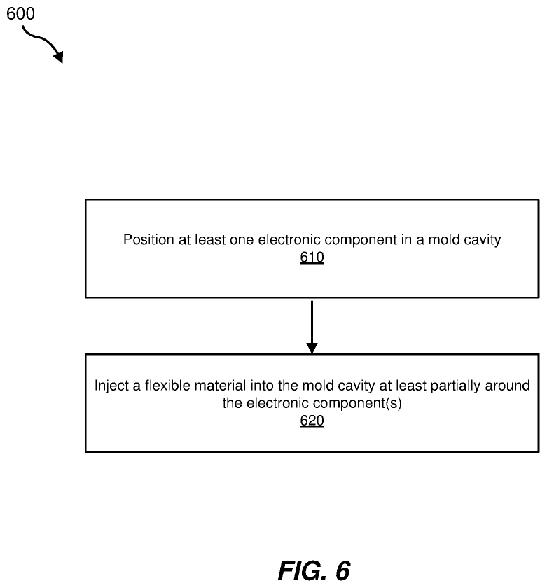

FIG. 6 is a flow diagram illustrating a method 500 of forming a wearable device, according to at least one embodiment of the present disclosure. At operation 610, at least one electronic component may be positioned in a mold cavity. Operation 610 may be performed in a variety of ways. For example, the mold cavity may have a shape of at least a portion of a wearable device, such as a wristband, armband, neckband, finger ring, glove, vest, headband, leg band, etc. The electronic component(s) may be any of the electronic components 112, 124 described above.

At operation 620, a flexible material may be injected into the mold cavity at least partially around the electronic component(s). Operation 620 may be performed in a variety of ways. For example, any of the flexible materials 110 described above may be injected in molten form and/or in viscous form into the mold cavity. Pressure within the mold cavity may be maintained below a predetermined pressure threshold (e.g., 50 MPa, 40 MPa, 30 MPa, 20 MPa, etc.) to inhibit damage to the electronic component(s). Similarly, temperature within the mold cavity may be maintained below a predetermined temperature threshold (e.g., 120° C., 110° C., 100° C., 90° C., 85° C., etc.), such as to inhibit demagnetization of components of a haptic actuator or degradation of electrical connections.

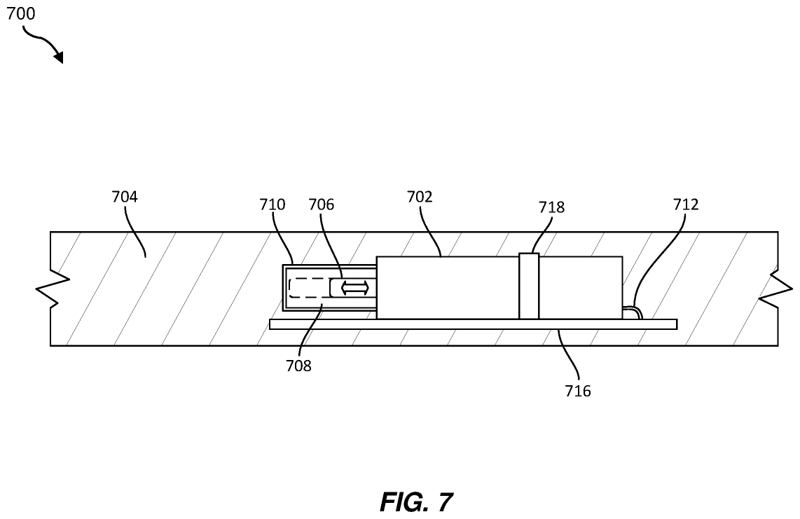

FIG. 7 is a cross-sectional view of a wearable device 700 including haptic actuator 702 overmolded by a flexible material 704, according to at least one embodiment of the present disclosure. The haptic actuator 702 may include a movable component 706. For example, the haptic actuator 702 may be an LRA and the movable component 706 may be an output shaft of the LRA. In additional embodiments, the haptic actuator 702 may be an ERM actuator, and the movable component 606 may be a rotatable mass.

For the haptic actuator 702 to operate properly, a cavity 708 may be formed within the flexible material 704 to provide space for the movable component 706 to move when activated. For example, a receptacle 710 may be located in a position to form and define the cavity 708. In some embodiments, the receptacle 710 may be coupled to a body of the haptic actuator 702 prior to overmolding the haptic actuator 702 with the flexible material 704. In additional embodiments, the receptacle 710 may be positioned within a mold cavity and the movable component 706 of the haptic actuator 702 may be disposed within the receptacle 710 prior to overmolding the haptic actuator 702 with the flexible material 704.

The haptic actuator 702 may be configured to mechanically withstand the pressures and temperatures present in an overmolding process that forms the flexible material 704. Thus, the haptic actuator 702 may be modified compared to conventional haptic actuators in a variety of ways. For example, the receptacle 710 and/or a body of the haptic actuator 702 may have an increased thickness, such as at least about 0.2 mm, 0.4 mm, 0.6 mm, or more. Additionally or alternatively, the haptic actuator 702 may be connected to a control circuit via a wired or pinned electrical connection 712, rather than a soldered connection. The haptic actuator 702 may be secured to a support substrate 716, such as a printed circuit board (PCB), with a bracket 718 (e.g., a metal bracket). The bracket 718 may inhibit (e.g., reduce or eliminate) shifting of the haptic actuator 702 during the overmolding process. Potential ingress points on the haptic actuator 702, such as at seams or component connection points, may be sealed to inhibit ingress of the flexible material 704 during the overmolding process. For example, an adhesive and/or tape may be used to cover the potential ingress points.

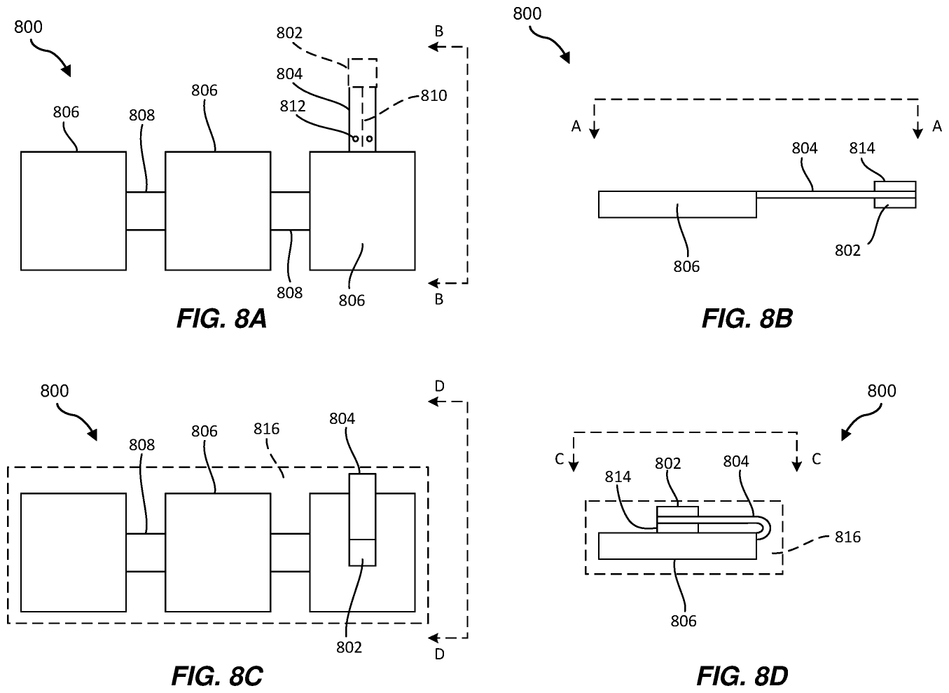

FIG. 8A is a plan view of a wearable device component 800 including an accelerometer 802 taken from line A-A of FIG. 8B, according to at least one embodiment of the present disclosure. FIG. 8B is a side view of the wearable device component 800 taken from line B-B of FIG. 8A. FIG. 8C is a plan view of the wearable device component 800 taken from line C-C of FIG. 8D after an extension 804 supporting the accelerometer 802 is folded into a final position. FIG. 8D is a side view of the wearable device component 800 taken from line D-D of FIG. 8C. The wearable device component 800 may be a rigid flex electrical component to be overmolded within a flexible material of a wearable device.

Referring to FIGS. 8A and 8B, the wearable device component 800 may include rigid substrates 806 (e.g., PCBs) separated by flexible electrical connections 808 to allow the rigid substrates 806 to rotate relative to each other as the resulting wearable device is flexed or bent. The accelerometer 802 may be coupled to one of the rigid substrates 806 via the extension 804, at least a portion of which may be flexible and bendable. The extension 804 may include one or more flexible electrical connectors 810 (e.g., a wire, a trace, etc.) for passing electrical signals from the accelerometer 802 to an electrical component on the rigid substrates 806. In some examples, a base of the extension 804 may also include one or more isolation features 812 (FIG. 8A), such as holes and/or notches. A standoff 814 (FIG. 8B) may be positioned on an opposite surface of the extension 804 from the accelerometer 802.

Referring to FIGS. 8C and 8D, prior to overmolding the wearable device component 800 with a flexible material 816, the extension 804 may be bent and folded to position the accelerometer 802 over a surface of one of the rigid substrates 806. The isolation features 812 may facilitate bending of the extension 804 by providing lower resistance to bending. The standoff 814 may rest against the rigid substrate 806. In some embodiments, the standoff 814 may not be adhered or otherwise secured to the rigid substrate 806, to further physically isolate the accelerometer 802 from the rigid substrate 806.

After overmolding is complete, the accelerometer 802 may be located close to a surface of the flexible material 816 that is to be positioned against the user's body (e.g., wrist). In additional examples, a surface of the accelerometer 802 may be substantially coplanar with the surface of the flexible material 816 or the accelerometer 802 may extend through an aperture in the flexible material 816.

Compared to embodiments in which an accelerometer is positioned directly on a rigid substrate, positioning the accelerometer 802 on the extension 804 may improve a performance of the accelerometer 802. The extension 804 may physically isolate the accelerometer 802 relative to the rigid substrate 806, while maintaining an electrical connection between the accelerometer 802 and electrical components on or in the rigid substrate 806. In addition, decoupling the standoff 814 from the rigid substrate 806 may further physically isolate the accelerometer 802 from the rigid substrate. The isolation features 812 may also improve the physical isolation of the accelerometer 802 from the rigid substrate 806 by reducing the level of movement or vibration that may be passed from the rigid substrate 806 through the extension 804 to the accelerometer 802. For example, in the configurations shown in FIGS. 8A-8D, vibrations or movement of the rigid substrate 806 may be reduced (e.g., dampened, eliminated, etc.) relative to the accelerometer 802 by one or more of the standoff 814, the extension 804, and/or the isolation features 812. In this manner, the accelerometer 802 may experience less vibrational noise to detect acceleration (e.g., vibration, motion, etc.) of the user rather than acceleration of the rigid substrate 806.

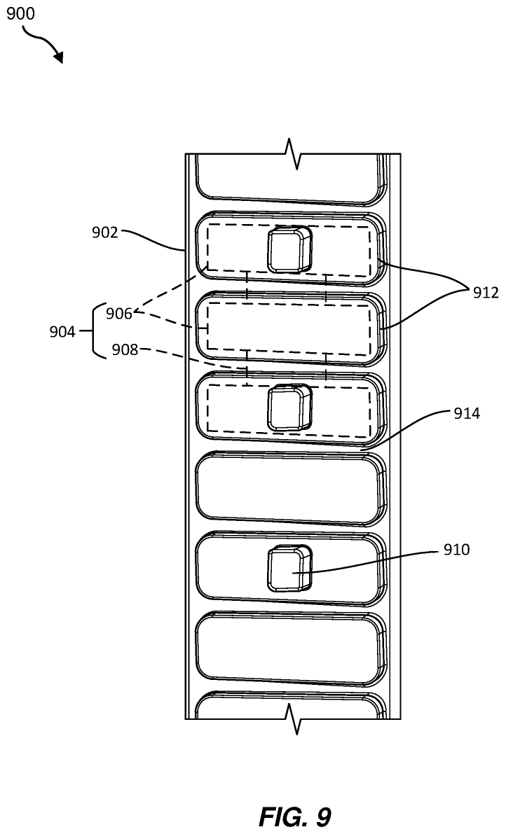

FIG. 9 is a perspective view of a portion of a wearable device 900, according to at least one additional embodiment of the present disclosure. For example, the wearable device 900 may include a strap (e.g., a wristband, a watchband, an armband, etc.) configured to wrap around a body part (e.g., a wrist, an arm, etc.) of a user for wearing the wearable device 900. The wearable device 900 may include a flexible material 902 overmolded over one or more electronic components, such as biometric sensors, motion sensors, haptic actuators, a power source, a processor, memory devices, communication elements, tracking elements, etc.

In some examples, the electronic components that are overmolded by the flexible material 902 may include a rigid flex PCB 904, which may include rigid substrates 906 electrically coupled to each other via flexible electrical connections 908. The electronic component(s) may be mounted to the rigid substrates 906. For example, sensing electrodes 910 may be mounted to the rigid substrates 906 and may protrude through the flexible material 902 to allow the sensing electrodes 910 to abut against the user's skin.

The flexible material 902 may have a shape and configuration that facilitates bending the wearable device 900 to wrap around a body part of the user without damaging the overmolded rigid flex PCB. For example, the flexible material 902 may include protruding segments 912 that at least partially cover the rigid substrates 906. The segments 912 may be separated by thinner sections 914 of the flexible material 902. When the wearable device 900 is flexed or bent, the flexible material 902 may tend to bend at the thinner sections 914 between the segments 912. This configuration may protect the rigid substrates 906 within the segments 912 and may allow the wearable device 900 to more readily conform to the user.

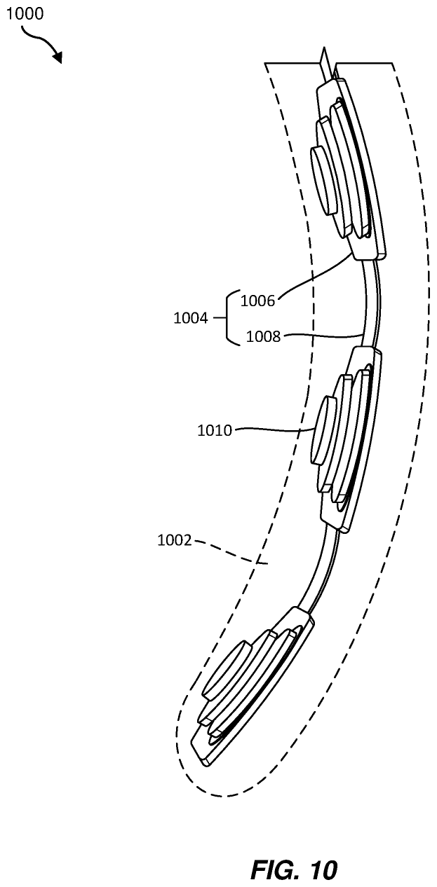

FIG. 10 is a perspective view of a portion of a wearable device 1000, according to at least one other embodiment of the present disclosure. The wearable device 1000 may include a strap (e.g., a wristband, a watchband, an armband, etc.) configured to wrap around a body part (e.g., a wrist, an arm, etc.) of a user for wearing the wearable device 100. The wearable device 1000 may include a flexible material 1002 overmolded over one or more electronic components, such as biometric sensors, motion sensors, haptic actuators, a power source, a processor, memory devices, communication elements, tracking elements, etc.

In some examples, the electronic components that are overmolded by the flexible material 1002 may include a rigid flex PCB 1004, which may include rigid substrates 1006 electrically coupled to each other via flexible electrical connections 1008. The electronic component(s) may be mounted to the rigid substrates 1006. For example, sensing electrodes 1010 may be mounted to the rigid substrates 1006 and may protrude through the flexible material 1002 to allow the sensing electrodes 1010 to abut against the user's skin.

In this example, the rigid flex PCB 1004 may be at least partially overmolded by the flexible material 1002 in an initially curved shape, as illustrated in FIG. 10. For example, the rigid flex PCB 1004 may be positioned within a mold that has a curved shape, and the flexible material 1002 (e.g., in a molten or uncured state) may be introduced into the curved mold to at least partially overmold the rigid flex PCB 1004. The curved shape of the flexible material 1002 may improve a bending performance of the flexible material 1002 and rigid flex PCB 1004 that is at least partially overmolded within the flexible material 1002. For example, in contrast to a flexible material 1002 that is formed in an initially straight (e.g., planar, flat, uncurved) shape, the curved flexible material 1002 may not require as much flexing to conform to a user's body part (e.g., arm, wrist, etc.). This curved configuration may place less strain on the flexible material 1002 and/or on the rigid flex PCB 1004 when worn and may result in easier donning of the wearable article 1000. In addition, the initially curved flexible material 1002 may tend to buckle or warp less than a comparable initially straight flexible material.

In some embodiments, the sensing electrodes 1010 may be provided in electrode pairs. In this case, there may be two sensing electrodes 1010 mounted to each rigid substrate 1006. The sensing electrodes 1010 may be positioned on the wearable device 1000 in locations to sense one or more desired signals. For example, the sensing electrodes 1010 may include neuromuscular sensors (e.g., electromyography (“EMG”) sensors) that may be used to sense neuromuscular signals associated with muscle movement and/or an intended muscle movement. The spacing and positioning of the sensing electrodes 1010 may be tailored to sense neuromuscular signals on a user's body part, such as an arm or wrist. By way of example and not limitation, the electrode pairs of the sensing electrodes 1010 may be between about 8 mm and about 16 mm, such as about 10 mm, about 12 mm, or about 14 mm, apart from each other. Each sensing electrode 1010 in a given electrode pair may be between about 10 mm and about 25 mm, such as about 15 mm or about 20 mm, apart from each other. In additional examples, the spacing of the sensing electrodes 1010 may be outside of these ranges, such as for different applications and/or for different users.

Accordingly, embodiments of the present disclosure may include wearable devices with at least one electronic component overmolded within a flexible material. The overmolded electronic component(s) may enable new and different form factors and functionality for wearable devices, such as wristwatches, wristbands, armbands, neckbands, finger rings, gloves, vests, headbands, leg bands, etc. For example, in the case of a wristwatch, components and functionality that are typically embodied by a watch body may be offloaded to an associated watchband, which may improve operation (e.g., operation speed, sensor sensitivity, tracking capabilities, etc.) of the wristwatch, reduce a size of the watch body, and/or increase battery life, among other potential improvements over conventional wristwatches.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

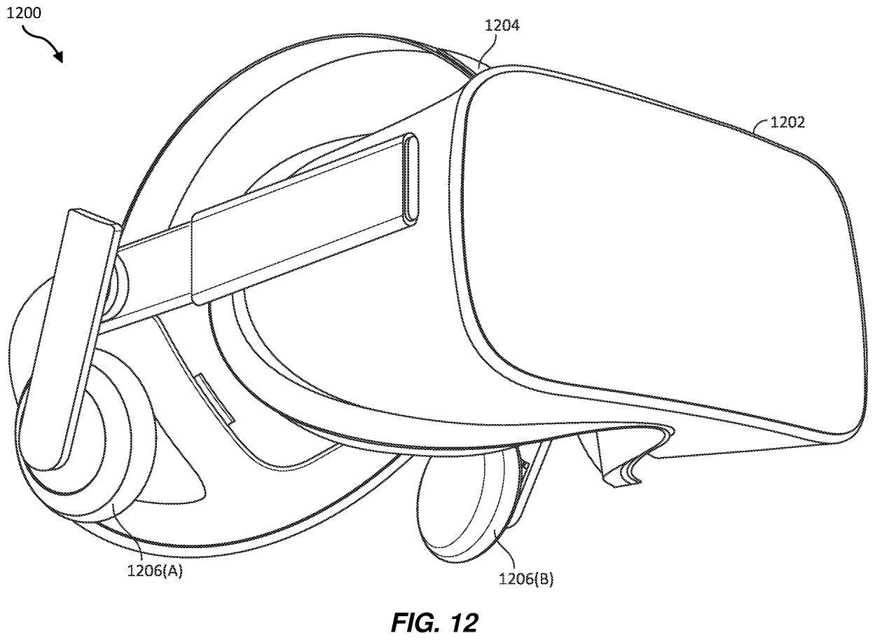

Artificial-reality systems may be implemented in a variety of different form factors and configurations. Some artificial-reality systems may be designed to work without near-eye displays (NEDs). Other artificial-reality systems may include an NED that also provides visibility into the real world (such as, e.g., augmented-reality system 1100 in FIG. 11) or that visually immerses a user in an artificial reality (such as, e.g., virtual-reality system 1200 in FIG. 12). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 11, the augmented-reality system 1100 may include an eyewear device 1102 with a frame 1110 configured to hold a left display device 1115(A) and a right display device 1115(B) in front of a user's eyes. The display devices 1115(A) and 1115(B) may act together or independently to present an image or series of images to a user. While the augmented-reality system 1100 includes two displays, embodiments of this disclosure may be implemented in augmented-reality systems with a single NED or more than two NEDs.

In some embodiments, the augmented-reality system 1100 may include one or more sensors, such as sensor 1140. The sensor 1140 may generate measurement signals in response to motion of the augmented-reality system 1100 and may be located on substantially any portion of the frame 1110. The sensor 1140 may represent one or more of a variety of different sensing mechanisms, such as a position sensor, an IMU, a depth-camera assembly, a structured light emitter and/or detector, or any combination thereof. In some embodiments, the augmented-reality system 1100 may or may not include the sensor 1140 or may include more than one sensor. In embodiments in which the sensor 1140 includes an IMU, the IMU may generate calibration data based on measurement signals from the sensor 1140. Examples of the sensor 1140 may include, without limitation, accelerometers, gyroscopes, magnetometers, other suitable types of sensors that detect motion, sensors used for error correction of the IMU, or some combination thereof.

In some examples, the augmented-reality system 1100 may also include a microphone array with a plurality of acoustic transducers 1120(A)-1120(J), referred to collectively as acoustic transducers 1120. The acoustic transducers 1120 may represent transducers that detect air pressure variations induced by sound waves. Each acoustic transducer 1120 may be configured to detect sound and convert the detected sound into an electronic format (e.g., an analog or digital format). The microphone array in FIG. 11 may include, for example, ten acoustic transducers: 1120(A) and 1120(B), which may be designed to be placed inside a corresponding ear of the user, acoustic transducers 1120(C), 1120(D), 1120(E), 1120(F), 1120(G), and 1120(H), which may be positioned at various locations on the frame 1110, and/or acoustic transducers 1120(I) and 1120(J), which may be positioned on a corresponding neckband 1105.

In some embodiments, one or more of the acoustic transducers 1120(A)-(J) may be used as output transducers (e.g., speakers). For example, the acoustic transducers 1120(A) and/or 1120(B) may be earbuds or any other suitable type of headphone or speaker.

The configuration of the acoustic transducers 1120 of the microphone array may vary. While the augmented-reality system 1100 is shown in FIG. 11 as having ten acoustic transducers 1120, the number of acoustic transducers 1120 may be greater or less than ten. In some embodiments, using higher numbers of acoustic transducers 1120 may increase the amount of audio information collected and/or the sensitivity and accuracy of the audio information. In contrast, using a lower number of acoustic transducers 1120 may decrease the computing power required by an associated controller 1150 to process the collected audio information. In addition, the position of each acoustic transducer 1120 of the microphone array may vary. For example, the position of an acoustic transducer 1120 may include a defined position on the user, a defined coordinate on the frame 1110, an orientation associated with each acoustic transducer 1120, or some combination thereof.

The acoustic transducers 1120(A) and 1120(B) may be positioned on different parts of the user's ear, such as behind the pinna, behind the tragus, and/or within the auricle or fossa. Or, there may be additional acoustic transducers 1120 on or surrounding the ear in addition to the acoustic transducers 1120 inside the ear canal. Having an acoustic transducer 1120 positioned next to an ear canal of a user may enable the microphone array to collect information on how sounds arrive at the ear canal. By positioning at least two of the acoustic transducers 1120 on either side of a user's head (e.g., as binaural microphones), the augmented-reality device 1100 may simulate binaural hearing and capture a 3D stereo sound field around about a user's head. In some embodiments, the acoustic transducers 1120(A) and 1120(B) may be connected to the augmented-reality system 1100 via a wired connection 1130, and in other embodiments the acoustic transducers 1120(A) and 1120(B) may be connected to the augmented-reality system 1100 via a wireless connection (e.g., a Bluetooth connection). In still other embodiments, the acoustic transducers 1120(A) and 1120(B) may not be used at all in conjunction with the augmented-reality system 1100.

The acoustic transducers 1120 on the frame 1110 may be positioned in a variety of different ways, including along the length of the temples, across the bridge, above or below the display devices 1115(A) and 1115(B), or some combination thereof. The acoustic transducers 1120 may also be oriented such that the microphone array is able to detect sounds in a wide range of directions surrounding the user wearing the augmented-reality system 1100. In some embodiments, an optimization process may be performed during manufacturing of the augmented-reality system 1100 to determine relative positioning of each acoustic transducer 1120 in the microphone array.

In some examples, the augmented-reality system 1100 may include or be connected to an external device (e.g., a paired device), such as the neckband 1105. The neckband 1105 generally represents any type or form of paired device. Thus, the following discussion of the neckband 1105 may also apply to various other paired devices, such as any of the wearable devices 100, 200, 300, 600 discussed above, charging cases, smart watches, smart phones, wrist bands, other wearable devices, hand-held controllers, tablet computers, laptop computers, other external compute devices, etc.

As shown, the neckband 1105 may be coupled to the eyewear device 1102 via one or more connectors. The connectors may be wired or wireless and may include electrical and/or non-electrical (e.g., structural) components. In some cases, the eyewear device 1102 and the neckband 1105 may operate independently without any wired or wireless connection between them. While FIG. 11 illustrates the components of the eyewear device 1102 and the neckband 1105 in example locations on the eyewear device 1102 and neckband 1105, the components may be located elsewhere and/or distributed differently on the eyewear device 1102 and/or neckband 1105. In some embodiments, the components of the eyewear device 1102 and neckband 1105 may be located on one or more additional peripheral devices paired with the eyewear device 1102, neckband 1105, or some combination thereof.

Pairing external devices, such as the neckband 1105, with augmented-reality eyewear devices may enable the eyewear devices to achieve the form factor of a pair of glasses while still providing sufficient battery and computation power for expanded capabilities. Some or all of the battery power, computational resources, and/or additional features of the augmented-reality system 1100 may be provided by a paired device or shared between a paired device and an eyewear device, thus reducing the weight, heat profile, and form factor of the eyewear device overall while still retaining desired functionality. For example, the neckband 1105 may allow components that would otherwise be included on an eyewear device to be included in the neckband 1105 since users may tolerate a heavier weight load on their shoulders than they would tolerate on their heads. The neckband 1105 may also have a larger surface area over which to diffuse and disperse heat to the ambient environment. Thus, the neckband 1105 may allow for greater battery and computation capacity than might otherwise have been possible on a standalone eyewear device. Since weight carried in the neckband 1105 may be less invasive to a user than weight carried in the eyewear device 1102, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

The neckband 1105 may be communicatively coupled with the eyewear device 1102 and/or to other devices. These other devices may provide certain functions (e.g., tracking, localizing, depth mapping, processing, storage, etc.) to the augmented-reality system 1100. In the embodiment of FIG. 11, the neckband 1105 may include two acoustic transducers (e.g., 1120(I) and 1120(J)) that are part of the microphone array (or potentially form their own microphone subarray). The neckband 1105 may also include a controller 1125 and a power source 1135.

The acoustic transducers 1120(I) and 1120(J) of the neckband 1105 may be configured to detect sound and convert the detected sound into an electronic format (analog or digital). As shown in FIG. 11, the acoustic transducers 1120(I) and 1120(J) may be positioned on the neckband 1105, thereby increasing the distance between the neckband acoustic transducers 1120(I) and 1120(J) and other acoustic transducers 1120 positioned on the eyewear device 1102. In some cases, increasing the distance between the acoustic transducers 1120 of the microphone array may improve the accuracy of beamforming performed via the microphone array. For example, if a sound is detected by the acoustic transducers 1120(C) and 1120(D) and the distance between the acoustic transducers 1120(C) and 1120(D) is greater than, e.g., the distance between the acoustic transducers 1120(D) and 1120(E), the determined source location of the detected sound may be more accurate than if the sound had been detected by the acoustic transducers 1120(D) and 1120(E).

The controller 1125 of the neckband 1105 may process information generated by the sensors on the neckband 1105 and/or the augmented-reality system 1100. For example, the controller 1125 may process information from the microphone array that describes sounds detected by the microphone array. For each detected sound, the controller 1125 may perform a direction-of-arrival (DOA) estimation to estimate a direction from which the detected sound arrived at the microphone array. As the microphone array detects sounds, the controller 1125 may populate an audio data set with the information. In embodiments in which the augmented-reality system 1100 includes an IMU, the controller 1125 may compute all inertial and spatial calculations from the IMU located on the eyewear device 1102. A connector may convey information between the augmented-reality system 1100 and the neckband 1105 and between the augmented-reality system 1100 and the controller 1125. The information may be in the form of optical data, electrical data, wireless data, or any other transmittable data form. Moving the processing of information generated by the augmented-reality system 1100 to the neckband 1105 may reduce weight and heat in the eyewear device 1102, making it more comfortable to the user.

The power source 1135 in the neckband 1105 may provide power to the eyewear device 1102 and/or to the neckband 1105. The power source 1135 may include, without limitation, lithium ion batteries, lithium-polymer batteries, primary lithium batteries, alkaline batteries, or any other form of power storage. In some cases, the power source 1135 may be a wired power source. Including the power source 1135 on the neckband 1105 instead of on the eyewear device 1102 may help better distribute the weight and heat generated by the power source 1135.

As noted, some artificial-reality systems may, instead of blending an artificial reality with actual reality, substantially replace one or more of a user's sensory perceptions of the real world with a virtual experience. One example of this type of system is a head-worn display system, such as the virtual-reality system 1200 shown in FIG. 12, that mostly or completely covers a user's field of view. The virtual-reality system 1200 may include a front rigid body 1202 and a band 1204 shaped to fit around a user's head. The virtual-reality system 1200 may also include output audio transducers 1206(A) and 1206(B). Furthermore, while not shown in FIG. 12, the front rigid body 1202 may include one or more electronic elements, including one or more electronic displays, one or more IMUs, one or more tracking emitters or detectors, and/or any other suitable device or system for creating an artificial-reality experience.

Artificial-reality systems may include a variety of types of visual feedback mechanisms. For example, display devices in the augmented-reality system 1100 and/or the virtual-reality system 1200 may include one or more LCDs, LED displays, OLED displays, DLP micro-displays, LCoS micro-displays, touch-screen displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., conventional concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in the augmented-reality system 1100 and/or virtual-reality system 1200 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, the augmented-reality system 1100 and/or virtual-reality system 1200 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (e.g., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

As noted, the artificial-reality systems 1100 and 1200 may be used with a variety of other types of devices to provide a more compelling artificial-reality experience. These devices may be haptic interfaces with transducers that provide haptic feedback and/or that collect haptic information about a user's interaction with an environment. The artificial-reality systems disclosed herein may include various types of haptic interfaces that detect or convey various types of haptic information, including tactile feedback (e.g., feedback that a user detects via nerves in the skin, which may also be referred to as cutaneous feedback) and/or kinesthetic feedback (e.g., feedback that a user detects via receptors located in muscles, joints, and/or tendons).

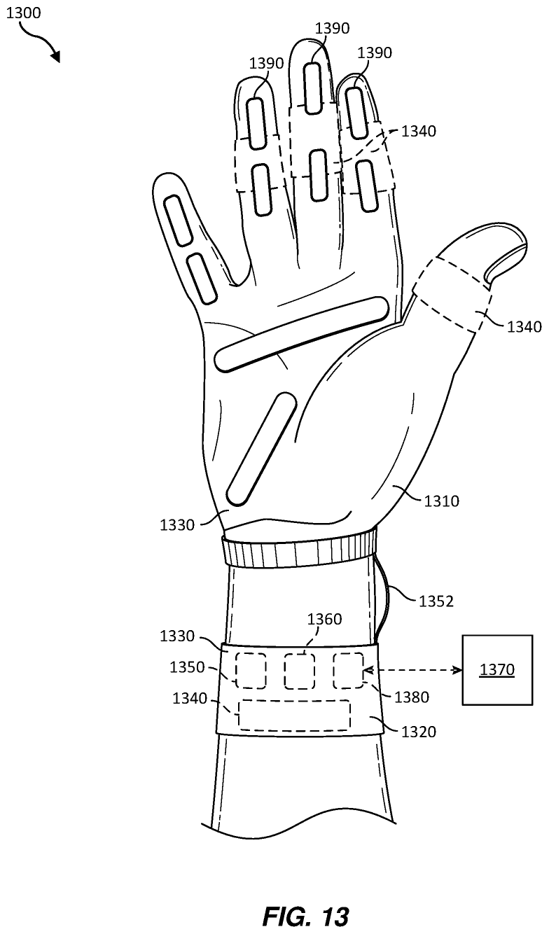

Haptic feedback may be provided by interfaces positioned within a user's environment (e.g., chairs, tables, floors, etc.) and/or interfaces on articles that may be worn or carried by a user (e.g., gloves, wristbands, etc.). As an example, FIG. 13 illustrates a vibrotactile system 1300 in the form of a wearable glove (haptic device 1310) and wristband (haptic device 1320). The haptic device 1310 and haptic device 1320 are shown as examples of wearable devices that include a flexible, wearable textile material 1330 that is shaped and configured for positioning against a user's hand and wrist, respectively. Any of the wearable devices 100, 200, 300, 600 described above may be implemented as haptic device 1310 and/or haptic device 1320. This disclosure also includes vibrotactile systems that may be shaped and configured for positioning against other human body parts, such as a finger, an arm, a head, a torso, a foot, or a leg. By way of example and not limitation, vibrotactile systems according to various embodiments of the present disclosure may also be in the form of a glove, a headband, an armband, a sleeve, a head covering, a sock, a shirt, or pants, among other possibilities. In some examples, the term “textile” may include any flexible, wearable material, including woven fabric, non-woven fabric, leather, cloth, a flexible polymer material, composite materials, etc.

One or more vibrotactile devices 1340 may be positioned at least partially within one or more corresponding pockets formed in the textile material 1330 of the vibrotactile system 1300. The vibrotactile devices 1340 may be positioned in locations to provide a vibrating sensation (e.g., haptic feedback) to a user of the vibrotactile system 1300. For example, the vibrotactile devices 1340 may be positioned against the user's finger(s), thumb, or wrist, as shown in FIG. 13. The vibrotactile devices 1340 may, in some examples, be sufficiently flexible to conform to or bend with the user's corresponding body part(s).

A power source 1350 (e.g., a battery) for applying a voltage to the vibrotactile devices 1340 for activation thereof may be electrically coupled to the vibrotactile devices 1340, such as via conductive wiring 1352. In some examples, each of the vibrotactile devices 1340 may be independently electrically coupled to the power source 1350 for individual activation. In some embodiments, a processor 1360 may be operatively coupled to the power source 1350 and configured (e.g., programmed) to control activation of the vibrotactile devices 1340.

The vibrotactile system 1300 may be implemented in a variety of ways. In some examples, the vibrotactile system 1300 may be a standalone system with integral subsystems and components for operation independent of other devices and systems. As another example, the vibrotactile system 1300 may be configured for interaction with another device or system 1370. For example, the vibrotactile system 1300 may, in some examples, include a communications interface 1380 for receiving and/or sending signals to the other device or system 1370. The other device or system 1370 may be a mobile device, a gaming console, an artificial-reality (e.g., virtual-reality, augmented-reality, mixed-reality) device, a personal computer, a tablet computer, a network device (e.g., a modem, a router, etc.), a handheld controller, etc. The communications interface 1380 may enable communications between the vibrotactile system 1300 and the other device or system 1370 via a wireless (e.g., Wi-Fi, Bluetooth, cellular, radio, etc.) link or a wired link. If present, the communications interface 1380 may be in communication with the processor 1360, such as to provide a signal to the processor 1360 to activate or deactivate one or more of the vibrotactile devices 1340.

The vibrotactile system 1300 may optionally include other subsystems and components, such as touch-sensitive pads 1390, pressure sensors, motion sensors, position sensors, lighting elements, and/or user interface elements (e.g., an on/off button, a vibration control element, etc.). During use, the vibrotactile devices 1340 may be configured to be activated for a variety of different reasons, such as in response to the user's interaction with user interface elements, a signal from the motion or position sensors, a signal from the touch-sensitive pads 1390, a signal from the pressure sensors, a signal from the other device or system 1370, etc.

Although the power source 1350, processor 1360, and communications interface 1380 are illustrated in FIG. 13 as being positioned in the haptic device 1320, the present disclosure is not so limited. For example, one or more of the power source 1350, processor 1360, or communications interface 1380 may be positioned within the haptic device 1310 or within another wearable textile.

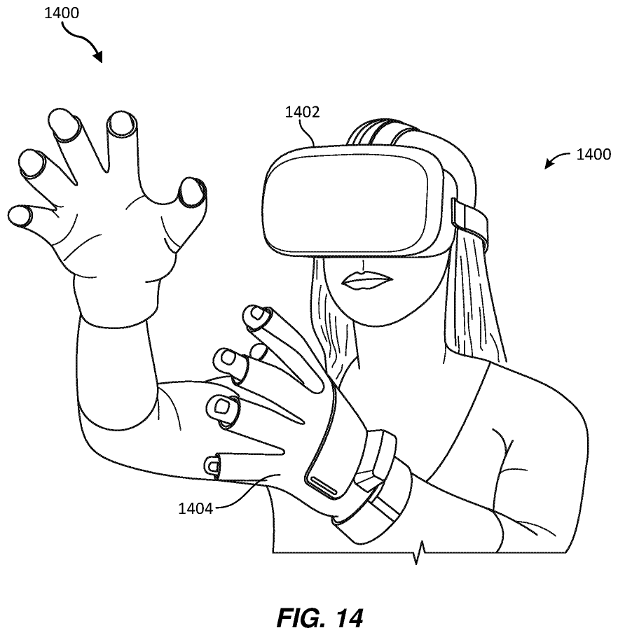

Haptic wearables, such as those shown in and described in connection with FIG. 13, may be implemented in a variety of types of artificial-reality systems and environments. FIG. 14 shows an example artificial-reality environment 1400 including one head-mounted virtual-reality display and two haptic devices (e.g., gloves), and in other embodiments any number and/or combination of these components and other components may be included in an artificial-reality system. For example, in some embodiments there may be multiple head-mounted displays each having an associated haptic device, with each head-mounted display and each haptic device communicating with the same console, portable computing device, or other computing system.

Head-mounted display 1402 generally represents any type or form of virtual-reality system, such as the virtual-reality system 1200 in FIG. 12. Haptic device 1404 generally represents any type or form of wearable device, worn by a user of an artificial-reality system, that provides haptic feedback to the user to give the user the perception that he or she is physically engaging with a virtual object. In some embodiments, the haptic device 1404 may provide haptic feedback by applying vibration, motion, and/or force to the user. For example, the haptic device 1404 may limit or augment a user's movement. To give a specific example, the haptic device 1404 may limit a user's hand from moving forward so that the user has the perception that his or her hand has come in physical contact with a virtual wall. In this specific example, one or more actuators within the haptic device may achieve the physical-movement restriction by pumping fluid into an inflatable bladder of the haptic device. In some examples, a user may also use the haptic device 1404 to send action requests to a console. Examples of action requests include, without limitation, requests to start an application and/or end the application and/or requests to perform a particular action within the application.

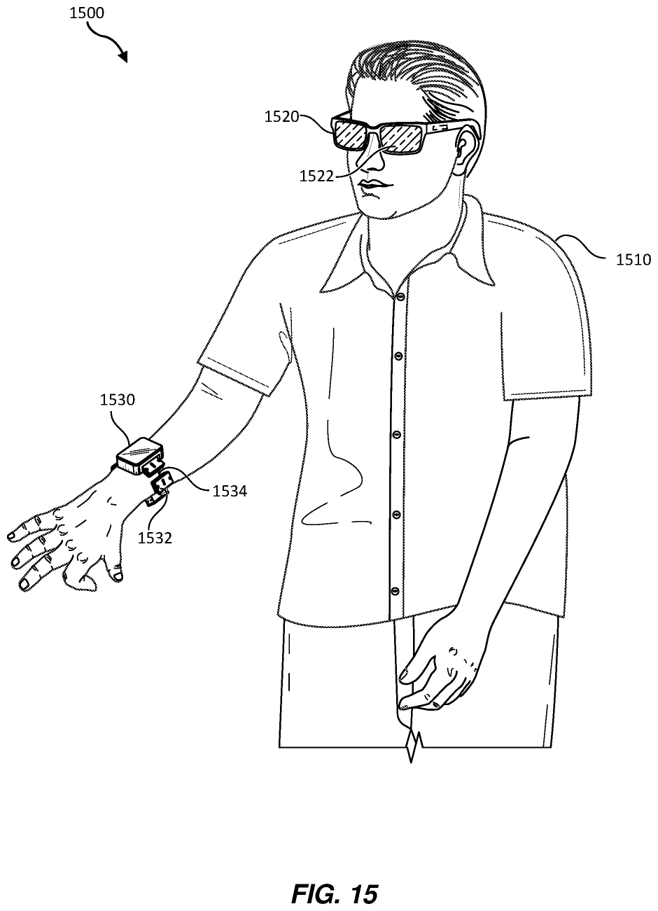

While haptic interfaces may be used with virtual-reality systems, as shown in FIG. 14, haptic interfaces may also be used with augmented-reality systems, as shown in FIG. 15. FIG. 15 is a perspective view of a user 1510 interacting with an augmented-reality system 1500. In this example, the user 1510 may wear a pair of augmented-reality glasses 1520 that may have one or more displays 1522 and that are paired with a haptic device 1530. In this example, the haptic device 1530 may be a wristband that includes a plurality of band elements 1532 and a tensioning mechanism 1534 that connects the band elements 1532 to one another.

One or more of the band elements 1532 may include any type or form of actuator suitable for providing haptic feedback. For example, one or more of the band elements 1532 may be configured to provide one or more of various types of cutaneous feedback, including vibration, force, traction, texture, and/or temperature. To provide such feedback, the band elements 1532 may include one or more of various types of actuators. In one example, each of the band elements 1532 may include a vibrotactor (e.g., a vibrotactile actuator) configured to vibrate in unison or independently to provide one or more of various types of haptic sensations to a user. Alternatively, only a single band element or a subset of band elements may include vibrotactors.

The haptic devices 1310, 1320, 1404, and 1530 may include any suitable number and/or type of haptic transducer, sensor, and/or feedback mechanism. For example, the haptic devices 1310, 1320, 1404, and 1530 may include one or more mechanical transducers, piezoelectric transducers, and/or fluidic transducers. The haptic devices 1310, 1320, 1404, and 1530 may also include various combinations of different types and forms of transducers that work together or independently to enhance a user's artificial-reality experience. In one example, each of the band elements 1532 of haptic device 1530 may include a vibrotactor (e.g., a vibrotactile actuator) configured to vibrate in unison or independently to provide one or more of various types of haptic sensations to a user.

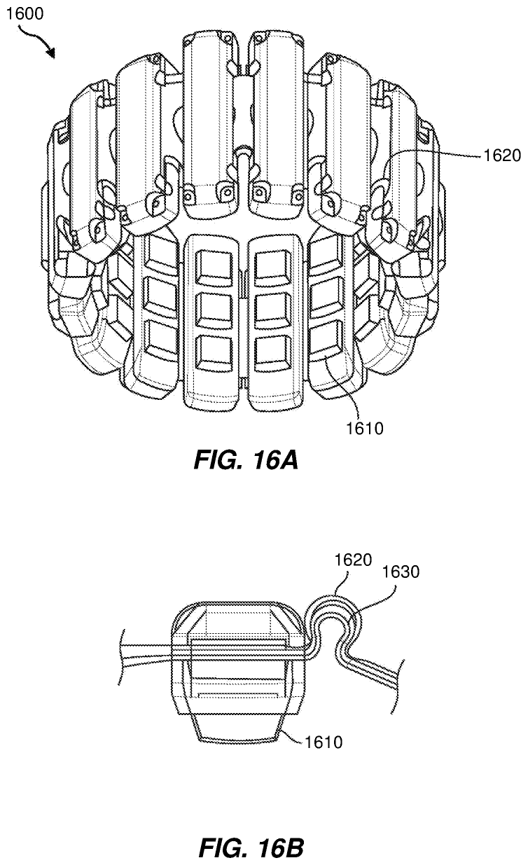

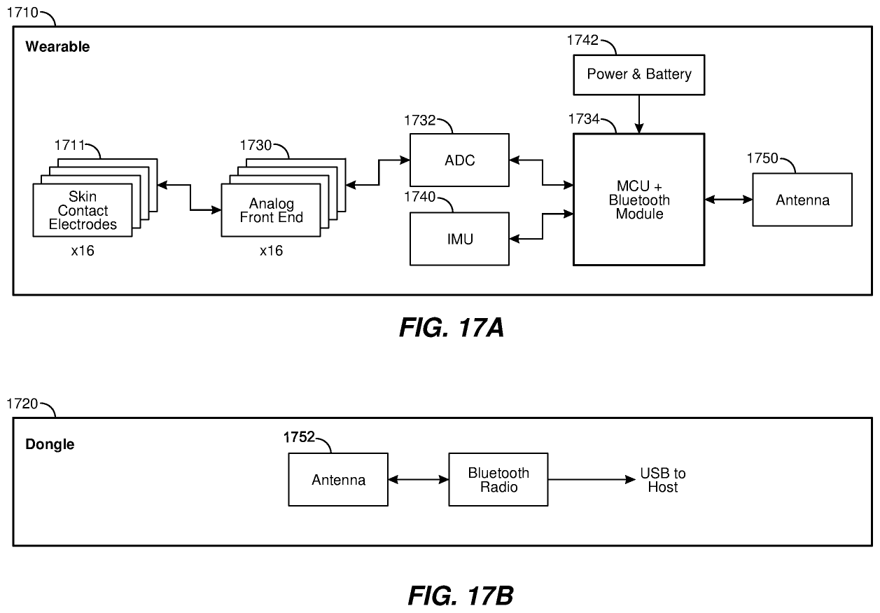

FIG. 16A illustrates an exemplary human-machine interface (also referred to herein as an EMG control interface) configured to be worn around a user's lower arm or wrist as a wearable system 1600. In this example, wearable system 1600 may include sixteen neuromuscular sensors 1610 (e.g., EMG sensors) arranged circumferentially around an elastic band 1620 with an interior surface configured to contact a user's skin. However, any suitable number of neuromuscular sensors may be used. The number and arrangement of neuromuscular sensors may depend on the particular application for which the wearable device is used. For example, a wearable armband or wristband can be used to generate control information for controlling an augmented reality system, a robot, controlling a vehicle, scrolling through text, controlling a virtual avatar, or any other suitable control task. As shown, the sensors may be coupled together using flexible electronics incorporated into the wireless device. FIG. 16B illustrates a cross-sectional view through one of the sensors of the wearable device shown in FIG. 16A. In some embodiments, the output of one or more of the sensing components can be optionally processed using hardware signal processing circuitry (e.g., to perform amplification, filtering, and/or rectification). In other embodiments, at least some signal processing of the output of the sensing components can be performed in software. Thus, signal processing of signals sampled by the sensors can be performed in hardware, software, or by any suitable combination of hardware and software, as aspects of the technology described herein are not limited in this respect. A non-limiting example of a signal processing chain used to process recorded data from sensors 1610 is discussed in more detail below with reference to FIGS. 17A and 17B.

FIGS. 17A and 17B illustrate an exemplary schematic diagram with internal components of a wearable system with EMG sensors. As shown, the wearable system may include a wearable portion 1710 (FIG. 17A) and a dongle portion 1720 (FIG. 17B) in communication with the wearable portion 1710 (e.g., via BLUETOOTH or another suitable wireless communication technology). As shown in FIG. 17A, the wearable portion 1710 may include skin contact electrodes 1711, examples of which are described in connection with FIGS. 16A and 16B. The output of the skin contact electrodes 1711 may be provided to analog front end 1730, which may be configured to perform analog processing (e.g., amplification, noise reduction, filtering, etc.) on the recorded signals. The processed analog signals may then be provided to analog-to-digital converter 1732, which may convert the analog signals to digital signals that can be processed by one or more computer processors. An example of a computer processor that may be used in accordance with some embodiments is microcontroller (MCU) 1734, illustrated in FIG. 17A. As shown, MCU 1734 may also include inputs from other sensors (e.g., IMU sensor 1740), and power and battery module 1742. The output of the processing performed by MCU 1734 may be provided to antenna 1750 for transmission to dongle portion 1720 shown in FIG. 17B.

Dongle portion 1720 may include antenna 1752, which may be configured to communicate with antenna 1750 included as part of wearable portion 1710. Communication between antennas 1750 and 1752 may occur using any suitable wireless technology and protocol, non-limiting examples of which include radiofrequency signaling and BLUETOOTH. As shown, the signals received by antenna 1752 of dongle portion 1720 may be provided to a host computer for further processing, display, and/or for effecting control of a particular physical or virtual object or objects.

Although the examples provided with reference to FIGS. 16A-16B and FIGS. 17A-17B are discussed in the context of interfaces with EMG sensors, the techniques described herein for reducing electromagnetic interference can also be implemented in wearable interfaces with other types of sensors including, but not limited to, mechanomyography (MMG) sensors, sonomyography (SMG) sensors, and electrical impedance tomography (EIT) sensors. The techniques described herein for reducing electromagnetic interference can also be implemented in wearable interfaces that communicate with computer hosts through wires and cables (e.g., USB cables, optical fiber cables, etc.).

The following example embodiments are also included in the present disclosure.

Example 1: A wearable device, which may include: a wearable body sized and configured to be worn on a user's body part, the wearable body comprising a flexible material for wrapping at least partially around the user's body part; and at least one electronic component within the wearable body, wherein the at least one electronic component is overmolded within the flexible material of the wearable body.

Example 2: The wearable device of Example 1, wherein the wearable body may include a watchband.

Example 3: The wearable device of Example 1 or Example 2, wherein the flexible material may include a silicone material.

Example 4: The wearable device of any of Examples 1 through 3, wherein the at least one electronic component may include at least one of: a biometric sensor, a position sensor, an orientation sensor, a haptic actuator, a power source, a light-emitting diode, or a printed circuit board.

Example 5: The wearable device of any of Examples 1 through 4, wherein the at least one electronic component may include a haptic actuator and the flexible material may include at least one cavity within which a movable component of the haptic actuator moves when activated.

Example 6: The wearable device of any of Examples 1 through 5, wherein the at least one electronic component may include a rigid flex printed circuit board.

Example 7: The wearable device of any of Examples 1 through 6, wherein the at least one electronic component may include an infrared light-emitting diode and the flexible material is at least partially transparent to infrared light.

Example 8: The wearable device of any of Examples 1 through 7, wherein the at least one electronic component may include a power source that is at least one of: curved, or flexible.

Example 9: The wearable device of Example 8, wherein the power source may include at least one battery cell.

Example 10: The wearable device of any of Examples 1 through 9, wherein the at least one electronic component may include an electrode that is exposed through the flexible material.

Example 11: A wristwatch, which may include: a watch body including at least one processor; and at least one watchband coupled to the watch body and configured to wrap at least partially around a user's arm, the at least one watchband including: a flexible material; and at least one electronic component overmolded at least partially within the flexible material.

Example 12: The wristwatch of Example 11, wherein the at least one electronic component may be in electronic communication with the processor of the watch body

Example 13: The wristwatch of Example 11 or Example 12, wherein the at least one watchband may include a first watchband coupled to a first side of the watch body and a second watchband coupled to a second, opposite side of the watch body.

Example 14: A method of forming a wearable device, which may include: positioning at least one electronic component within a mold cavity having a shape of at least a portion of a wristband; and injecting a flexible material into the mold cavity at least partially around the at least one electronic component to overmold the electronic component.

Example 15: The method of any of Example 14, wherein positioning the at least one electronic component with the mold cavity may include positioning at least one of the following within the mold cavity: a biometric sensor, a position sensor, an orientation sensor, a haptic actuator, a power source, a light-emitting diode, or a printed circuit board.

Example 16: The method of Example 14 or Example 15, which may further include maintaining a pressure within the mold cavity below a predetermined pressure threshold to inhibit damage to the at least one electronic component.

Example 17: The method of Example 16, wherein the predetermined pressure threshold may be about 50 MPa or less.

Example 18: The method of any of Examples 14 through 17, which may further include maintaining a temperature within the mold cavity below a predetermined temperature threshold to inhibit damage to the at least one electronic component.

Example 19: The method of Example 18, wherein the predetermined temperature threshold may be about 120° C. or less.

Example 20: The method of any of Examples 14 through 19, wherein injecting the flexible material into the mold cavity may include injecting a silicone material into the mold cavity.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various example methods described and/or illustrated herein may also omit one or more of the steps described or illustrated herein or include additional steps in addition to those disclosed.

The preceding description has been provided to enable others skilled in the art to best utilize various aspects of the example embodiments disclosed herein. This example description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A wearable device, comprising:
a wearable body sized and configured to be worn on a user's body part, the wearable body comprising a flexible material for wrapping at least partially around the user's body part; and
at least one electronic component within the wearable body, wherein the at least one electronic component is overmolded within the flexible material of the wearable body.

2. The wearable device of claim 1, wherein the wearable body comprises a watchband.

3. The wearable device of claim 1, wherein the flexible material comprises a silicone material.

4. The wearable device of claim 1, wherein the at least one electronic component comprises at least one of:
a biometric sensor;
a position sensor;
an orientation sensor;
a haptic actuator;
a power source;
a light-emitting diode; or
a printed circuit board.

5. The wearable device of claim 1, wherein the at least one electronic component comprises a haptic actuator and the flexible material includes at least one cavity within which a movable component of the haptic actuator moves when activated.

6. The wearable device of claim 1, wherein the at least one electronic component comprises a rigid flex printed circuit board.

7. The wearable device of claim 1, wherein the at least one electronic component comprises an infrared light-emitting diode and the flexible material is at least partially transparent to infrared light.

8. The wearable device of claim 1, wherein the at least one electronic component comprises a power source that is at least one of:
curved; or
flexible.

9. The wearable device of claim 8, wherein the power source comprises at least one battery cell.

10. The wearable device of claim 1, wherein the at least one electronic component comprises an electrode that is exposed through the flexible material.

11. A wristwatch, comprising:
a watch body comprising at least one processor; and
at least one watchband coupled to the watch body and configured to wrap at least partially around a user's arm, the at least one watchband comprising:
a flexible material; and
at least one electronic component overmolded at least partially within the flexible material.

12. The wristwatch of claim 11, wherein the at least one electronic component is in electronic communication with the processor of the watch body.

13. The wristwatch of claim 11, wherein the at least one watchband comprises a first watchband coupled to a first side of the watch body and a second watchband coupled to a second, opposite side of the watch body.

14. A method of forming a wearable device, comprising:
positioning at least one electronic component within a mold cavity having a shape of at least a portion of a wristband; and
injecting a flexible material into the mold cavity at least partially around the at least one electronic component to overmold the electronic component.

15. The method of claim 14, wherein positioning the at least one electronic component with the mold cavity comprises positioning at least one of the following within the mold cavity:
a biometric sensor;
a position sensor;
an orientation sensor;
a haptic actuator;
a power source;
a light-emitting diode; or
a printed circuit board.

16. The method of claim 14, further comprising maintaining a pressure within the mold cavity below a predetermined pressure threshold to inhibit damage to the at least one electronic component.

17. The method of claim 16, wherein the predetermined pressure threshold is about 50 MPa or less.

18. The method of claim 14, further comprising maintaining a temperature within the mold cavity below a predetermined temperature threshold to inhibit damage to the at least one electronic component.

19. The method of claim 18, wherein the predetermined temperature threshold is about 120° C. or less.

20. The method of claim 14, wherein injecting the flexible material into the mold cavity comprises injecting a silicone material into the mold cavity.
